(19) United States
(12) Patent Application Publication
(10) Pub. No.: US 2005/0083663 A1
(43) Pub. Date: Apr. 21, 2005

(54) Electronic device and method for manufacturing the same

(75) Inventor: Kenji Inoue, Tokyo (JP)

Correspondence Address: Sean M. McGinn;McGinn & Gibb, PLLC, Suite 200, 8321 Old Courthouse Road, Vienna, VA, 22182-3817, US

(73) Assignee: TDK Corporation, Tokyo (JP)

(21) Appl. No.: 10/959,978

(22) Filed: Oct. 8, 2004

(30) Foreign Application Priority Data
Oct. 20, 2003 (JP) 2003-358779

(51) Int. Cl. H05K 7/06

(52) U.S. Cl. 361/760; 361/783

(57) ABSTRACT

An electronic device includes: a complex module having a semiconductor device 12 and a plurality of resonators 13a, 13b formed on a single device board 11 and electrically separated from one another; and a printed circuit board 14 on which the complex module is mounted and which electrically connects the resonator 13a judged as a conforming product to the semiconductor device 12 through bumps 22 formed in the resonator 13a.

### BACKGROUND OF THE INVENTION

1. Field of the Invention

The present invention relates to an electronic device and more particularly to the electronic device which is capable of preventing a decrease in a yield caused by a defect in a resonator in an RF (Radio Frequency) module fabricated by integrating resonators into a semiconductor device such as a monolithic VCO (Voltage Controlled Oscillator).

2. Description of the Related Art

A resonator, an SMR (Solidly Mounted Resonator)-type resonator in particular, among piezo-resonators using a bulk acoustic wave being made to propagate through an piezoelectric film, since it is not necessary to keep the resonator in a hollow state unlike in the case of a diaphragm-type piezoelectric thin-film resonator, has a high applicability to an RF module (electronic device) fabricated by integrating the resonator into a semiconductor device and, therefore, becomes a focus of attention A module obtained by integrating an SMR-type resonator into a semiconductor device is disclosed in U.S. Pat. No. 3,414,832.

However, a piezo-resonator such as an SMR-type resonator, unlike in the case of a semiconductor device, is easily affected by a local defect in a piezoelectric film caused by existence of an impurity, peeling of a film, or a like and its characteristic is influenced greatly by a mechanical structure.

That is, even when a yield of a comparatively high-priced semiconductor device, a manufacturing process of which is complicated, is increased, if a case in which a module becomes defective as a whole due to a local defect in comparatively low-priced piezo-resonator occurs frequently, an increase in costs is unavoidable. Such the problem as above occurs commonly not only in the piezo-resonator but also in an SAW (Surface Acoustic Wave) resonator.

### SUMMARY OF THE INVENTION

In view of the above, it is an object of the present invention to provide an electronic device which is capable of preventing a decrease in a yield caused by a defect in a resonator and a method for manufacturing the electronic device.

According to a first aspect of the present invention, there is provided an electronic device including:
a module having two or more resonators formed on a single device board and electrically separated from one another; and
a printed circuit board on which the module is mounted and to which a partial number of resonators is electrically connected through conductive units formed in the partial number of resonators.

According to a second aspect of the present invention, there is provided an electronic device including:
a complex module having a semiconductor device and two or more resonators formed on a single device board and the semiconductor device is electrically separated from each of the two or more resonators; and
a printed circuit board on which the complex module is mounted and which electrically connects a partial number of resonators to the semiconductor device through conductive units formed in the partial number of the resonators.

According to a third aspect of the present invention, there is provided an electronic device including:
a semiconductor module having a semiconductor device formed on a first device board;
a resonator module having two or more resonators formed on a second device board and electrically separated from one another; and
a printed circuit board on which the semiconductor module and the resonator module are mounted and which electrically connects the resonator to the semiconductor device through conductive units formed in a partial number of the resonators.

In the foregoing, a preferable mode is one wherein a partial number of the resonators out of the two or more resonators is electrically connected to the semiconductor device through a device-side bump formed in an electrode pad, which serves connection to the resonator, in the semiconductor device, through a resonator-side bump serving as the conductive unit and being formed in an electrode pad, which serves connection to the semiconductor device, in the resonator to be electrically connected to the semiconductor device, and through a conductive land formed on the printed circuit board and being able connectable to the device-side bump and to the resonator-side bump formed in electrode pads, which serve connection to the semiconductor device, in all the resonators.

According to a fourth aspect of the present invention, there is provided an electrode device including:
a complex module having a semiconductor device formed on a single device board, two or more resonators formed on the single device board and electrically separated from one another, and two or more switching units arranged between the semiconductor device and each of the two or more resonators wherein a partial number of the two or more switching units is turned on to connect the semiconductor device and the resonator, and
a printed circuit board on which the complex module is mounted.

In the foregoing, a preferable mode is one wherein the two or more switching units are an electronic switch made up of a diode or MOSFET (Metal Oxide Semiconductor Field Effect Transistor).

Also, a preferable mode is one wherein each of the two or more resonators has a same frequency characteristic and wherein the resonator being connected to the semiconductor device is a resonator having been judged as a conforming product.

Also, a preferable mode is one wherein each of the two or more resonators has a different frequency characteristic and wherein the resonator being connected to the semiconductor device is a resonator having a frequency characteristic being more matched to a characteristic of the semiconductor device.

Also, a preferable mode is one wherein the resonator is a piezo-resonator which obtains a signal having a specified resonant frequency by a bulk acoustic wave propagating through an inner portion of a piezoelectric film.

Also, a preferable mode is one wherein the piezo-resonator is an SMR-type piezo-resonator.

According to a fifth aspect of the present invention, there is provided a method for manufacturing an electronic device including:
a step of preparing a module formed on a single device board and having two or more resonators electrically separated from one another;
a step of forming a bump in an electrode pad in a partial number of the two or more resonators;
a step of preparing a printed circuit board on which a conductive land is formed which is connectable to bumps formed in an electrode pads of all the resonators; and
a step of mounting the module so that the bump formed in a partial number of resonators is connected to the land.

According to a sixth aspect of the present invention, there is provided a method for manufacturing an electronic device including:
a step of preparing a complex module formed on a single device board and having a semiconductor device and two or more resonators electrically separated from one another;
a step of forming a device-side bump in an electrode pad, which serves connection to a resonator, in the semiconductor device and of forming a resonator-side bump in electrode pads, which serves connection to the semiconductor device, in a partial number of the resonators;
a step of preparing a printed circuit board having a conductive land being connectable to the device-side bump and the resonator-side bump formed in electrode pads, which serve connection to the semiconductor device, in all the resonators; and
a step of mounting the complex module on the printed circuit board so that the device-side bump is connected to the resonator-side bump formed in a partial number of the resonators.

According to a seventh aspect of the present invention, there is provided a method for manufacturing an electronic device including:
a step of preparing a semiconductor module having a semiconductor device formed on a first device board;
a step of forming a device-side bump in an electrode pad, which serves connection to a resonator, in the semiconductor device;
a step of preparing a resonator module having two or more resonators formed on a second device board and electrically separated from one another;
a step of forming resonator-side bumps in electrode pads, which serve connection to the semiconductor device, in a partial number of the resonators;
a step of preparing a printed circuit board on which a conductive land being connectable to the device-side bump and the resonator-side bumps formed in all the resonators is formed; and
a step of mounting the semiconductor module in a state in which the device-side bump is connected to the land and of mounting the resonator module in a state in which the resonator-side bumps formed in a partial number of the resonators are connected to the land.

According to an eighth aspect of the present invention, there is provided a method for manufacturing an electronic device including:
a step of preparing a complex module having a semiconductor device formed on a single device board, two or more resonators electrically separated from one another formed on the single device board, and switching units being arranged between the semiconductor device and each of the two or more resonators;
a step of turning on a partial number of the switching units to electrically connect the semiconductor device to the resonator through the switching units; and
a step of mounting the complex module.

In the foregoing, a preferable mode is one wherein each of the two or more resonators has a same frequency characteristic and wherein the resonator having been judged as a conforming product is connected to the semiconductor device.

Also, a preferable mode is one wherein each of the two or more resonators has a different frequency characteristic and wherein the resonator having a frequency characteristic being more matched to a characteristic of the semiconductor device is connected to the semiconductor device.

With the above configuration, two or more resonators formed on a device board are partially connected to one another and, therefore, a desired resonator can be selectively used. In particular, by forming two or more resonators having a same characteristic on a device board and by providing a piezo-resonator judged as a conforming product with an electrically conductive means and by mounting the piezo-resonator with the conductive means on a printed circuit board, the piezo-resonator being judged as the conforming product can be selectively connected, through the printed circuit board, to a semiconductor device and, therefore, a decrease in a yield caused by a defect in a piezo-resonator can be prevented.

With another configurations as above, when an SMR-type piezo-resonator is used as a resonator and when the resonator and the semiconductor device are formed on a same device board, since both the resonator and the semiconductor device are electrically connected, by using the conductive means, through the printed circuit board, a process of connecting the semiconductor device to the SMR-type piezo-resonator by mounting an electrode of the semiconductor device and an electrode of the SMR-type piezo-resonator stereoscopically formed on a same layer is not required and, therefore, costs can be reduced.

### BRIEF DESCRIPTION OF THE DRAWINGS

The above and other objects, advantages, and features of the present invention will be more apparent from the following description taken in conjunction with the accompanying drawings in which:

FIG. 1 is a plan view of a complex module making up an electronic device of a first embodiment of the present invention;

FIG. 2 is a plan view of a printed circuit board on which the complex module of FIG. 1 is mounted;

FIG. 3 is a cross-sectional view showing the electronic device fabricated by mounting the complex module of FIG. 1 on the printed circuit board of FIG. 2;

FIG. 4 is a plan view of a complex module making up an electronic device of a second embodiment of the present invention;

FIG. 5 is a plan view of a printed circuit board on which the complex module of FIG. 1 is mounted according to the second embodiment of the present invention; and

FIG. 6 is a cross-sectional view of an electronic device fabricated by mounting the complex module of FIG. 4 on the printed circuit board according to the second embodiment of the present invention;

### DETAILED DESCRIPTION OF THE PREFERRED EMBODIMENTS

Best modes of carrying out the present invention will be described in further detail using various embodiments with reference to the accompanying drawings. In the accompanying drawings, same reference numbers are assigned to same parts and duplicated description is omitted accordingly. Here, the best mode of carrying the present invention is described and, therefore, the present invention is not limited to embodiments described below.

### First Embodiment

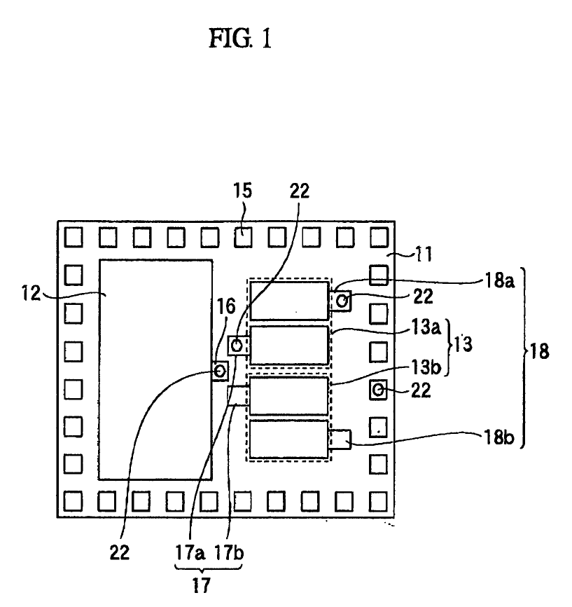

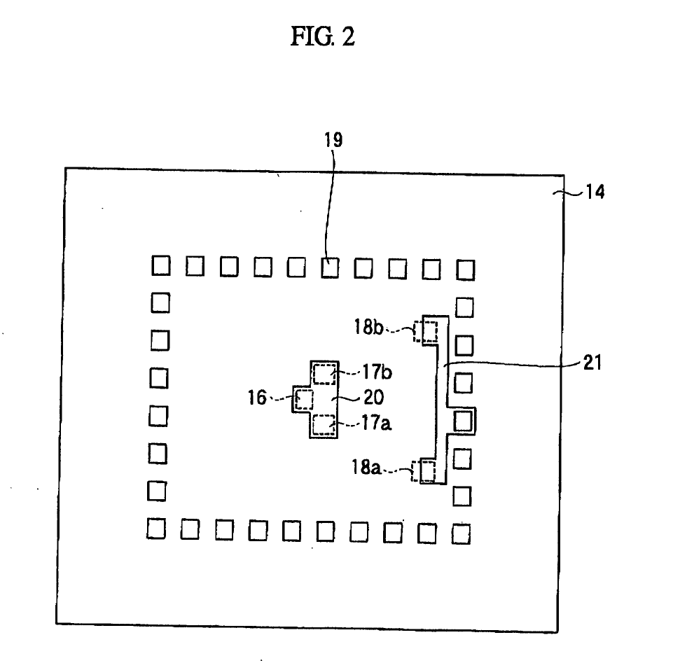

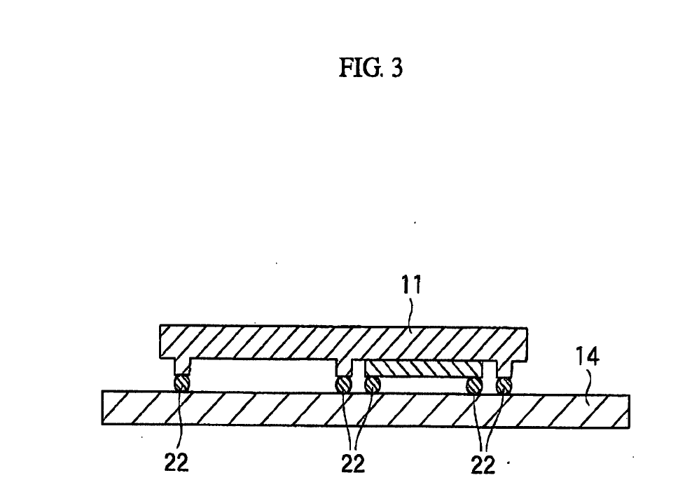

FIG. 1 is a plan view of a complex module making up an electronic device of a first embodiment of the present invention. FIG. 2 is a plan view of a printed circuit board on which the complex module of FIG. 1 is mounted. FIG. 3 is a cross-sectional view showing the electronic device fabricated by mounting the complex module of FIG. 1 on the printed circuit board of FIG. 2.

As shown in FIG. 1, the complex module is made up of a single device board 11 made of an Si (silicon) single crystal or a like, a semiconductor device 12 being an integrated circuit constructed of a semiconductor device including a transistor or a like which is mounted on the device board 11, and two resonators, for example, SMR-type piezo-resonators (resonators) 13a and 13b both having a same characteristic which is also mounted on the device board 11. On the device board 11, the semiconductor device 12 and two piezo-resonators 13a and 13b are electrically separated from one another. Moreover, the SMR-type piezo-resonator is a resonator in which a signal having a specified resonant frequency is obtained by a bulk wave being made to propagate through an inner portion of a piezoelectric film and which occurs when an alternate current is applied to a lower electrode and an upper electrode formed with the piezoelectric film being interposed between the lower electrode and the upper electrode.

In circumferential edge portions of the device board 11 is formed a plurality of electrode pads 15 used to electrically and mechanically connect the complex module to a printed circuit board 14 described later. In the vicinity of the semiconductor device 12 is formed an electrode pad 16 used to connect the semiconductor device 12 to the piezo-resonator 13. Furthermore, in the vicinity of the piezo-resonator 13 are formed electrode pads 17 used to connect the piezo-resonator 13 to the semiconductor device 12 and electrode pads 18 used to connect the piezo-resonator 13 to outside components. The electrode pad 16 is arranged in the vicinity of the electrode pads 17.

On the other hand, on the printed circuit board 14 on which the complex module is mounted is formed a plurality of electrodes 19 which are laid out so that each of the electrode pads 15 overlies each of the plurality of electrodes 19. Also, a conductive land 20 is laid out so that the electrode pad 16 and all the electrode pads 17 overlie the conductive land 20 in a manner in which the conductive land 20 is surrounded by the electrodes 19 and all the electrode pads 18 overlie the wiring electrode 21 being connected to one of the electrodes 19 in a manner in which the wiring electrode 21 is also surrounded by the electrodes 19. Moreover, in the above descriptions, when the word of “overlie” is used, the expression includes two meanings of “overlie partially” and of “overlie totally”.

Each of the electrode pads 15, 16, 17, and 18 has a bump in a form of a stud bump or a plating bump 22 having an area that can allow flip-chip mounting therein and each of the electrode pads 15 is connected, through the bump 22, to each of the electrodes 19 formed on the printed circuit board, and the land 20 is connected, through the bump 22, to the wiring electrode 21. Therefore, the semiconductor device 12 is electrically connected to the piezo-resonator 13 through the bump 22 formed in the electrode pad 16 on a side of the semiconductor device 12, the bump 22 (conductive means) formed in the electrode pad 16 on a side of the piezo-resonator 13, and the land 20 formed to connect the bump 22 on the side of the semiconductor device 12 to the bump 22 on the side of the piezo-resonator 13 when the complex module is mounted on the printed circuit board 14.

Moreover, in FIG. 1, only one bump 22 formed in the electrode pad 15 is shown, however, in reality, the bump 22 is formed in all the electrode pads 15. Also, as described above, since the land 20 is laid out so that the electrode pad 16 and all the electrode pads 17 are put on top of the land 20, the bump 22 formed in the electrode pad 16 can be connected to the bumps 22 formed in all the electrode pads 17.

The bump 22 is made of solder, gold, aluminum, or a like. Some element may be connected to the electrodes 19, land 20, and wiring electrode 21 formed on the printed circuit board 14.

Next, a method for manufacturing an electronic device having such configurations as above is described.

First, an on-wafer probing processing is performed on the complex module to judge whether each of the piezo-resonators 13a and 13b is a conforming product or a defective product and the result is held as data. Here, in the embodiment, let it be assumed that the piezo-resonator 13a is a conforming product and the piezo-resonator 13b is a defective product. As described above, since the piezo-resonators are electrically independent from one other, the judgement as to whether each of the piezo-resonators 13a and 13b is not defective or defective can be made with ease.

Next, according to the result from the judgement that the piezo-resonator 13a making up the complex module is a conforming product, the bump 22 is formed only in the electrode pads 17a and 18a making up the piezo-resonator 13a having been judged as the conforming product. As a result, the bump 22 is not formed in the electrode pads 17b and 18b making up the piezo-resonator 13b having been judged as the defective product. Moreover, the bump 22 is formed also in the electrode pads 15 and 16.

Then, the complex module is separated, by using a dicing method, into pieces. A flip-mounting operation is performed on the prepared printed circuit board 14 so that the bump 22 formed in the semiconductor device 12 and the bump 22 formed in the piezo-resonator 13a are connected to the land 20 (see FIG. 3). As a result, though the piezo-resonator 13a in which the bump 22 serving as a conductive means is formed is electrically connected to the semiconductor device 12 through the printed circuit board 14, the piezo-resonator 13b in which the bump 22 is not formed is electrically separated from the semiconductor device 12.

Moreover, if capacitive coupling among electrode pads 17a and 18b of the piezo-resonator 13b being not used and the land 20 and/or wiring electrode 21 corresponding to the above electrode pads 17a and 18b presents a problem, unwanted electrode pads 17a and 18b may be removed by using a laser trimming method.

Thus, according to the first embodiment of the present invention, two or more piezo-resonators such as the piezo-resonators 13a and 13b having a same characteristic are formed on the device board 11 and the bump 22 serving as the conductive means formed, for example, in the piezo-resonator 13a having been judged as a conforming product is mounted on the printed circuit board 14 and, therefore, the piezo-resonator 13a is connected to the semiconductor device 12 via the printed circuit board 14. Even if a failure caused by a local defect occurs in one piezo-resonator, the other piezo-resonator has a high possibility of being a conforming product and, therefore, by selecting the conforming piezo-resonator (the piezo-resonator 13a in the embodiment) and by connecting the selected conforming piezo-resonator to the semiconductor device 12, a decrease in a yield caused by the failure in the piezo-resonator can be prevented.

Moreover, in the conventional technology, when an SMR-type piezo-resonator, in particular, is used as the piezo-resonator, since the SMR-type piezo-resonatot is fabricated by stereoscopically stacking an acoustic multi-layer film, lower electrode, piezo-electrical layer, and upper electrode, if the semiconductor device has to be connected to the SMR-type piezo-resonator on the device board, a process of installing wiring of both an electrode of the semiconductor device 12 and an electrode of the SMR-type piezo-resonator on a same layer is required. However, according to the embodiment of the present invention, since the semiconductor device 12 is electrically connected to the SMR-type piezo-resonator via the bump 22 for a flip chip and the land 20 on the printed circuit board 14, the above process is not needed, thus enabling costs to be reduced.

### Second Embodiment

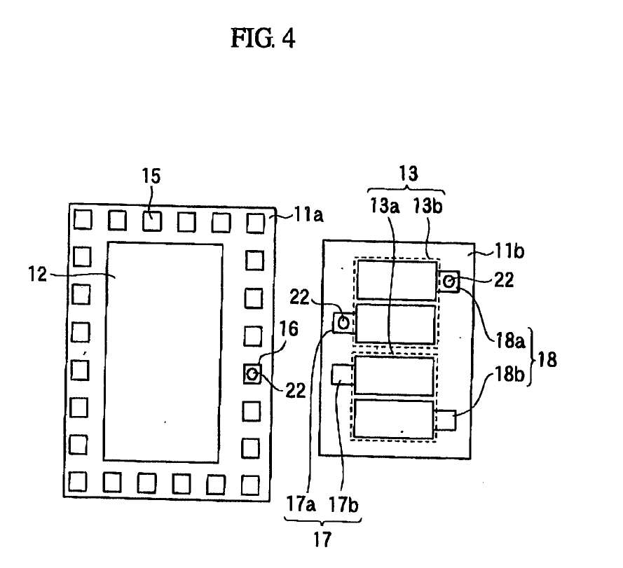

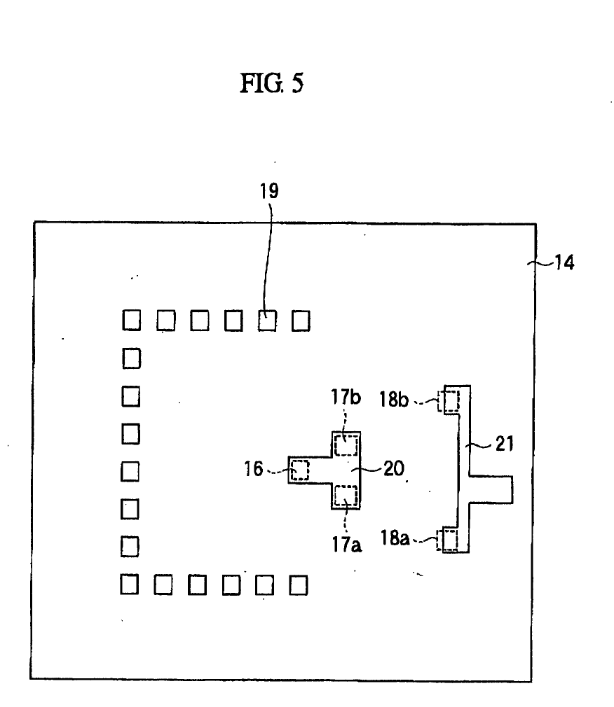

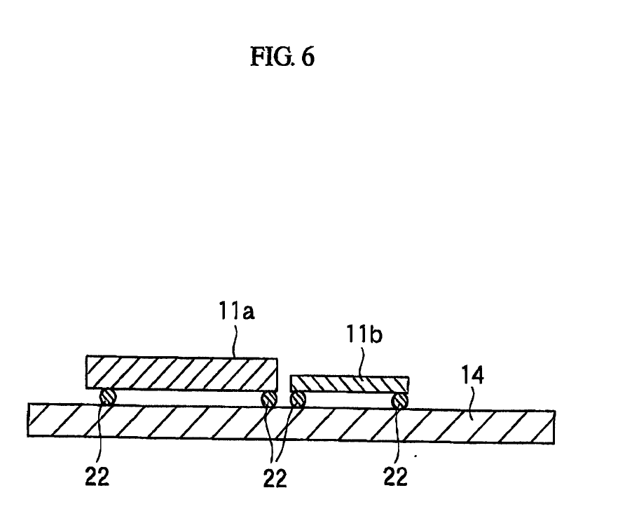

FIG. 4 is a plan view of a complex module making up an electronic device of a second embodiment of the present invention FIG. 5 is a plan view of a printed circuit board on which the complex module of FIG. 1 is mounted according to the second embodiment. FIG. 6 is a cross-sectional view of an electronic device fabricated by mounting the complex module of FIG. 4 on the printed circuit board of FIG. 5.

Unlike in the case of the first embodiment in which the semiconductor device 12 and the piezo-resonator 12 are formed on a same device board (see FIG. 1), in the second embodiment, a semiconductor device and a piezo-resonator are formed separately on different device boards.

That is, as shown in FIG. 4, a semiconductor device 12 is formed on a first device board 11a to construct a semiconductor module. Also, two or more piezo-resonators 13a and 13b being separated electrically from each one another are formed on a second device board 11b to construct a resonator module.

By forming the bumps 22 on the first and second device boards 11a and 11b in the same way as employed in the first embodiment and then by mounting the semiconductor module and the resonator module on the printed circuit board 14 (see FIGS. 5 and 6), the piezo-resonator 13a can be electrically connected to the semiconductor device 12 through the printed circuit board 14.

Thus, according to the present invention, by forming bumps serving as the conductive means on partial number of the piezo-resonators and by mounting the module on the printed circuit board 14 in the resonator module having two or more piezo-resonators electrically separated from one another and being mounted on a single device board, a partial number of the piezo-resonators (the piezo-resonator 13a in the embodiments) can be electrically connected to the printed circuit board 14 and other remaining number of the piezo-resonators (the piezo-resonator 13b in the embodiments) can be electrically separated.

It is apparent that the present invention is not limited to the above embodiments but may be changed and modified without departing from the scope and spirit of the invention. For example, in the above first embodiment of the present invention, the conforming piezo-resonator is selected by a mounting method, however, the conforming piezo-resonator may be selected by storing data being programmed to select the conforming piezo-resonator in a ROM (Read Only Memory) and by using a switching means such as an electronic switch serving as a high-frequency switch made up of a diode or MOSFET according to the data.

That is, by installing the switching means among the semiconductor device and piezo-resonators to electrically connect the semiconductor device and the piezo-resonators and by turning on the switching means corresponding to a piezo-resonator judged as a conforming product, electrical connection between the semiconductor device and piezo-resonators via the switching means is achieved. Then, the complex module is separated into pieces by the dicing method and the pieces of the separated component is mounted on the printed circuit board 14 according to the flip mounting method.

Also, in the above description, the two piezo-resonators 13a and 13b are configured so as to have a same frequency characteristic and the piezo-resonator 13a judged as the conforming product is connected to the semiconductor device 12, however, the number of the piezo-resonators is not limited to “two” and any number may be acceptable so long as the number of the piezo-resonators may be two or more.

Moreover, if all the piezo-resonators are judged as a conforming product, the semiconductor device 12 may be connected to any one of the piezo-resonators judged as the conforming product.

Also, two or more piezo-resonators may be configured so as to have frequencies being different from one another and the piezo-resonator having a frequency characteristic being more matched to a characteristic of the semiconductor device may be connected to the semiconductor device.

Then, by forming three or more piezo-resonators to connect two or more piezo-resonators to the semiconductor device, a filter or a duplexer may be incorporated therein.

Moreover, a configuration and shape of each of the semiconductor device 12, piezo-resonator 13, electrode 19, land 20, and wiring electrode 21 are merely one example and may be modified to meet aims.

In the above descriptions, the case in which the present invention is applied to the SMR-type piezo-resonator is explained. The present invention can be applied to a layer-stacked piezo-resonator operated by using a piezoelectric film such as a diaphragm-type piezo-resonator configured so that a bulk acoustic wave propagates easily by notching a part of the device board. Moreover, the present invention can be applied not only to such the piezo-resonator as described in the embodiment but also widely to a resonator made up of a thin film formed on a device board such as an SAW-type resonator operated by using an SAW.

1. An electronic device comprising:
a module having two or more resonators formed on a single device board and electrically separated from one another; and
a printed circuit board on which said module is mounted and to which a partial number of resonators is electrically connected through conductive units formed in said partial number of resonators.

2. An electronic device comprising:
a complex module having a semiconductor device and two or more resonators formed on a single device board and said semiconductor device is electrically separated from each of said two or more resonators; and
a printed circuit board on which said complex module is mounted and which electrically connects a partial number of resonators to said semiconductor device through conductive units formed in said partial number of said resonators.

3. An electronic device comprising:
a semiconductor module having a semiconductor device formed on a first device board;
a resonator module having two or more resonators formed on a second device board and electrically separated from one another; and
a printed circuit board on which said semiconductor module and said resonator module are mounted and which electrically connects said resonator to said semiconductor device through conductive units formed in a partial number of the resonators.

4. The electronic device according to claim 2, wherein a partial number of said resonators out of said two or more resonators is electrically connected to said semiconductor device through a device-side bump formed in an electrode pad, which serves connection to said resonator, in said semiconductor device, through a resonator-side bump serving as said conductive unit and being formed in an electrode pad, which serves connection to said semiconductor device, in said resonator to be electrically connected to said semiconductor device, and through a conductive land formed on said printed circuit board and being connectable to said device-side bump and to said resonator-side bump formed in electrode pads, which serve connection to said semiconductor device, in all said resonators.

5. An electrode device comprising:
a complex module having a semiconductor device formed on a single device board, two or more resonators formed on said single device board and electrically separated from one another, and two or more switching units arranged between said semiconductor device and each of said two or more resonators wherein a partial number of said two or more switching units is turned on to connect said semiconductor device and said resonator; and
a printed circuit board on which said complex module is mounted.

6. The electronic device according to claim 5, wherein said two or more switching units are an electronic switch made up of a diode or MOSFET (Metal Oxide Semiconductor Field Effect Transistor).

7. The electronic device according to claim 2, wherein each of said two or more resonators has a same frequency characteristic and wherein the resonator being connected to said semiconductor device IS comprises a resonator having been judged as a conforming product.

8. The electronic device according to claim 2, wherein each of said two or more resonators has a different frequency characteristic and wherein the resonator being connected to said semiconductor device is a resonator having a frequency characteristic being more matched to a characteristic of said semiconductor device.

9. The electronic device according to claim 1, wherein said resonator comprises a piezo-resonator which obtains a signal having a specified resonant frequency by a bulk acoustic wave propagating through an inner portion of a piezoelectric film.

10. The electronic device according to claim 9, wherein said piezo-resonator is an SMR (Solidly Mounted Resonator)-type piezo-resonator.

11. A method for manufacturing an electronic device comprising:
a step of preparing a module formed on a single device board and having two or more resonators electrically separated from one another;
a step of forming a bump in an electrode pad in a partial number of said two or more resonators;
a step of preparing a printed circuit board on which a conductive land is formed which is connectable to bumps formed in an electrode pads of all the resonators; and
a step of mounting said module so that said bump formed in a partial number of resonators is connected to said land.

12. A method for manufacturing an electronic device comprising:
a step of preparing a complex module formed on a single device board and having a semiconductor device and two or more resonators electrically separated from one another;
a step of forming a device-side bump in an electrode pad, which serves connection to a resonator, in said semiconductor device and of forming a resonator-side bump in electrode pads, which serves connection to said semiconductor device, in a partial number of said resonators;
a step of preparing a printed circuit board having a conductive land being connectable to said device-side bump and said resonator-side bump formed in electrode pads, which serve connection to said semiconductor device, in all the resonators; and
a step of mounting said complex module on said printed circuit board so that said device-side bump is connected to said resonator-side bump formed in a partial number of said resonators.

13. A method for manufacturing an electronic device comprising:
a step of preparing a semiconductor module having a semiconductor device formed on a first device board;
a step of forming a device-side bump in an electrode pad, which serves connection to a resonator, in said semiconductor device;
a step of preparing a resonator module having two or mare resonators formed on a second device board and electrically separated from one another;
a step of forming resonator-side bumps in electrode pads, which serve connection to said semiconductor device, in a partial number of the resonators;
a step of preparing a printed circuit board on which a conductive land being connectable to said device-side bump and said resonator-side bumps formed in all said resonators is formed; and
a step of mounting said semiconductor module in a state in which said device-side bump is connected to said land and of mounting said resonator module in a state in which said resonator-side bumps formed in a partial number of said resonators are connected to said land.

14. A method for manufacturing an electronic device comprising:
a step of preparing a complex module having a semiconductor device formed on a single device board, two or more resonators electrically separated from one another formed on said single device board, and switching units being arranged between said semiconductor device and each of said two or more resonators;
a step of turning on a partial number of said switching units to electrically connect said semiconductor device to the resonator through said switching units; and
a step of mounting said complex module.

15. The method for manufacturing the electronic device according to claim 12, wherein each of said two or more resonators has a same frequency characteristic and wherein the resonator having been judged as a conforming product is connected to said semiconductor device.

16. The method for manufacturing the electronic device according to claim 12, wherein each of said two or more resonators has a different frequency characteristic and wherein the resonator having a frequency characteristic being more matched to a characteristic of said semiconductor device is connected to said semiconductor device.

17. The electronic device according to claim 3, wherein a partial number of said resonators out of said two or more resonators is electrically connected to said semiconductor device through a device-side bump formed in an electrode pad, which serves connection to said resonator, in said semiconductor device, through a resonator-side bump serving as said conductive unit and being formed in an electrode pad, which serves connection to said semiconductor device, in said resonator to be electrically connected to said semiconductor device, and through a conductive land formed on said printed circuit board and being connectable to said device-side bump and to said resonator-side bump formed in electrode pads, which serve connection to said semiconductor device, in all said resonators.

18. The electronic device according to claim 3, wherein each of said two or more resonators has a same frequency characteristic and wherein the resonator being connected to said semiconductor device comprises a resonator having been judged as a conforming product.

19. The electronic device according to claim 4, wherein each of said two or more resonators has a same frequency characteristic and wherein the resonator being connected to said semiconductor device comprises a resonator having been judged as a conforming product.

20. The electronic device according to claim 5, wherein each of said two or more resonators has a same frequency characteristic and wherein the resonator being connected to said semiconductor device comprises a resonator having been judged as a conforming product.
